(19) United States
(12) Patent Application Publication
(10) Pub. No.: US 2014/0063988 A1
(43) Pub. Date: Mar. 6, 2014

(54) SEMICONDUCTOR MEMORY DEVICE

(71) Applicant: SK HYNIX INC., Icheon-si (KR)

(72) Inventors: In Soo LEE, Icheon-si (KR); Jung Hyuk YOON, Icheon-si (KR)

(73) Assignee: SK hynix Inc., Icheon-si (KR)

(21) Appl. No.: 13/720,917

(22) Filed: Dec. 19, 2012

(30) Foreign Application Priority Data
Aug. 29, 2012 (KR) 10-2012-0095214

(51) Int. Cl. G11C 7/00

(52) U.S. Cl. CPC G11C 7/00
USPC 365/189.16

(57) ABSTRACT

Disclosed is a semiconductor memory device. A semiconductor memory device in accordance with an embodiment of the present invention includes a write driver configured to provide voltage necessary for a write operation when the write operation is performed, a switch block connected to the write driver and configured to control the path of the write voltage, and a cell block connected to the switch block, wherein a constant voltage is supplied to a node leading to a cell selection path within the cell block using the write driver as a voltage source.

### CROSS-REFERENCES TO RELATED APPLICATION

The present application claims priority under 35 U.S.C. §119(a) to Korean application number 10-2012-0095214, filed on Aug. 29, 2012, in the Korean Intellectual Property Office, which is incorporated herein by reference in its entirety.

### BACKGROUND

1. Technical Field

The present invention generally relates to a memory device, and more particularly, to a semiconductor memory device.

2. Related Art

In general, a phase change memory device is characterized in that it has a data processing speed almost equal to that of random access memory (RAM) and retains data even when power is off.

The voltage levels of a phase change memory device used when a write operation and a read operation are performed are relatively high. If a memory cell is selected and a write or read operation is performed as described above, a load on a line is increased because a word line WL or a bit line BL is activated within a plurality of cell matrices, with the result that a lot of current is consumed.

Since there is a plurality of current paths, a normal write operation may not be performed because an electric current is not regularly divided according to circumstances. In order to solve this problem, voltage from a write driver can be increased in order to increase current supply force, but reliability of data is deteriorated because a distribution of resistance values is widened due to the resistance of current paths. Accordingly, there is a need for a technique for preventing excessive current consumption and reducing the deterioration of performance due to an increased load on a line.

### SUMMARY

In an embodiment, a semiconductor memory device includes a write driver configured to provide voltage necessary for a write operation when the write operation is performed, a switch block connected to the write driver and configured to control the path of the write voltage, and a cell block connected to the switch block, wherein a constant voltage is supplied to a node leading to a cell selection path within the cell block using the write driver as a voltage source.

In an embodiment, a semiconductor memory device includes a write driver configured to provide voltage necessary for a write operation when the write operation is performed, a cell block configured to include a plurality of pages into which data is written using the voltage received from the write driver when the write operation is performed, and a switch block provided between the write driver and the cell block and configured to provide the path of the write voltage from the write driver to the cell block, wherein the switch block includes a plurality of switch units, and when the plurality of switch units is provided to correspond to the respective pages, a cell selection path between the write driver and each of the pages is a single path.

### BRIEF DESCRIPTION OF THE DRAWINGS

Features, aspects, and embodiments are described in conjunction with the attached drawings, in which:

FIG. 1 shows the construction of a phase change memory device in accordance with an embodiment;

FIG. 2 is a block diagram of a switch controller of FIG. 1;

FIG. 3 is an equivalent circuit diagram of FIG. 1; and

FIG. 4 shows the construction of a phase change memory device in accordance with an embodiment.

### DETAILED DESCRIPTION

Hereinafter, a semiconductor memory device according to various embodiments will be described below with reference to the accompanying drawings through the embodiments.

Embodiments will be described based on phase change random access memory (PRAM). It is however evident to those skilled in the art that the embodiments can be applied to semiconductor memory devices including nonvolatile memory devices using resistant material, such as resistive RAM (RRAM) and ferroelectric RAM (FRAM).

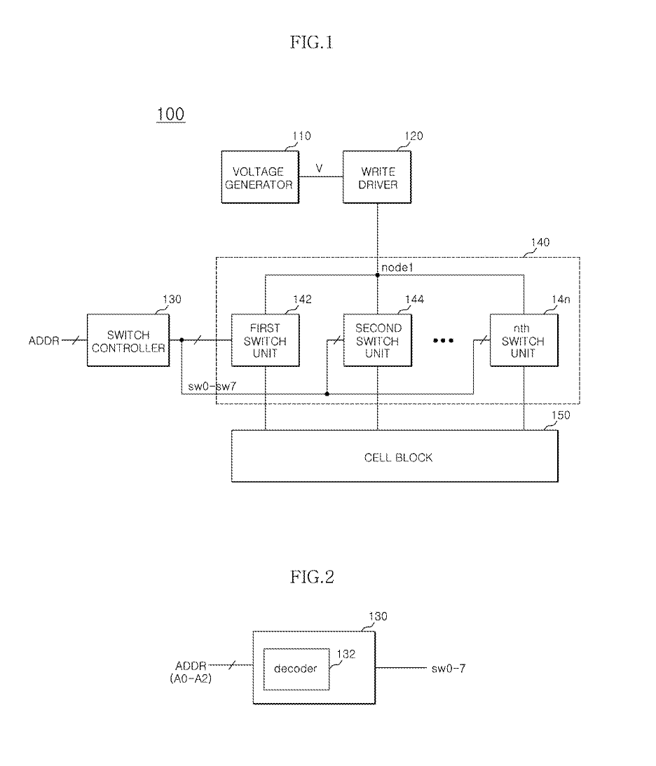

FIG. 1 shows the construction of a phase change memory device in accordance with an embodiment, and FIG. 2 is a block diagram of a switch controller of FIG. 1. First to third address signals ADDR A0-A2 are illustrated in FIG. 2, for convenience of description, but not limited thereto.

Referring to FIGS. 1 and 2, the phase change memory device 100 in accordance with an embodiment may include a voltage generator 110, a write driver 120, a switch controller 130, a switch block 140, and a cell block 150.

The voltage generator 110 may generate a specific high voltage V necessary when a write operation is performed. The voltage generator 110 is a common voltage generator that is understood by those skilled in the art, and thus a detailed description thereof is omitted.

The write driver 120 may receive the specific high voltage V and supply a write voltage regularly in response to a write command. The write driver 120 in accordance with an embodiment is illustrated as being a voltage source voltage source.

The switch controller 130 may supply a plurality of switch control signals SW0-SW7 in response to the address signals ADDR.

The switch controller 130 in accordance with an embodiment may provide the plurality of switch control signals so that the paths of write currents flowing through respective switch units 142, 144, . . . , 14n may be controlled as a single path in order to reduce a load on the current of the write driver 120 when the write driver 120 is considered as a voltage source.

The switch controller 130 may include a decoder 132, as shown in FIG. 2. The switch controller 130 may receive the first to third address signals A0-A2, for example, and provide the 8 switch control signals SW0-SW7 obtained by decoding the 3 address signals. However, the embodiments are not limited to these examples, and the address signals can be added or reduced by taking the construction of the circuit or the voltage supply ability of the write driver into consideration. Furthermore, an additional MRS signal may also be used. It is important to use the switch units of the switch block 140 as signals the turn-on/off of which can be controlled in order to satisfy an object of the various embodiments.

The switch block 140 is described below.

The switch block 140 may include the plurality of switch units 142, 144, . . . , 14n.

Each of the switch units 142, 144, . . . , 14n may receive the plurality of switch control signals SW0-SW7 and supply a voltage path from the write driver 120 to the cell block 150 in response to the enabled switch control signals SW0-SW7.

Additionally, voltage at a node node 1 may be supplied from the write driver 120 and viewed from each of the switch units 142, 144, . . . , 14n, is substantially the same.

The cell block 150 may include a matrix of a plurality of nonvolatile memory cells. The rows of the plurality of nonvolatile memory cells are coupled with respective word lines (not shown), and a column of the plurality of nonvolatile memory cells is coupled with a bit line (not shown). Here, the nonvolatile memory cell can include a variable resistance element (not shown) configured to include a phase change material having a different resistance value depending on a crystalline state or an amorphous state and an access element (not shown) configured to control an electric current flowing through the variable resistance element. For example, the access element (not shown) can be a diode or a transistor that is coupled with the variable resistance element (not shown) in series.

In accordance with an embodiment, a constant voltage may be supplied to the node node1 that reaches cell selection paths using the write driver 120 as a voltage source. Furthermore, resistance between the cell selection paths can be made constant by selecting the cell selection paths that range from the write driver 120 to the memory cells of the cell block 150 using the switch units 142, 144 . . . 14n. Accordingly, when a write operation is performed, the shortage of a write current can be prevented.

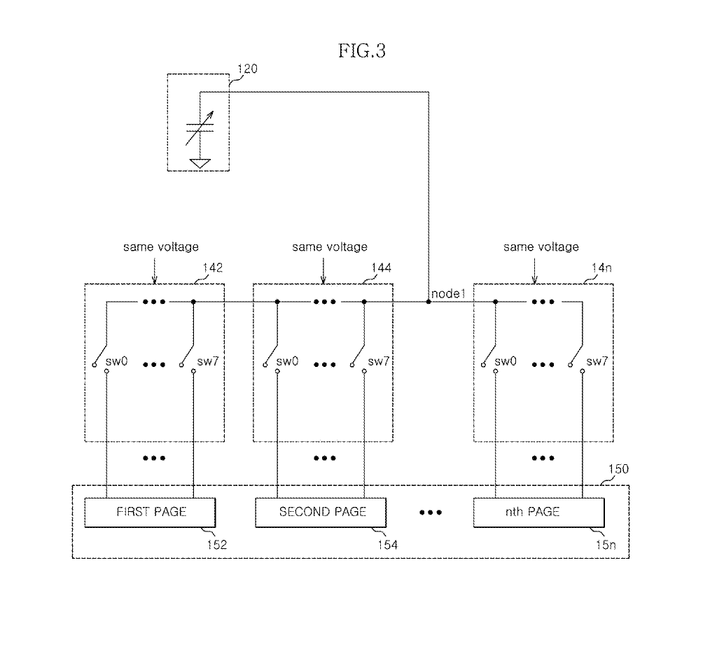

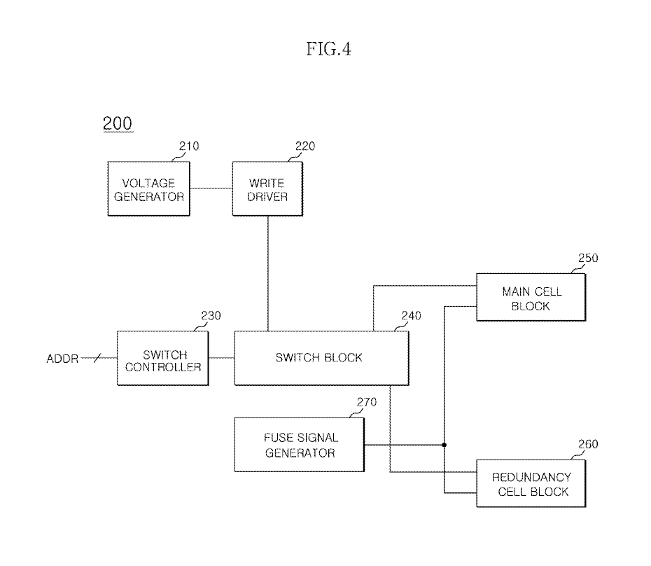

FIG. 3 is a simple equivalent circuit diagram for helping in the understanding of the write driver 120, the switch units 142, 144, . . . , 14n, and the cell block 150 of FIG. 1.

Various embodiments are described in detail with reference to FIG. 3.

Referring to FIG. 3, a constant voltage may be supplied from the write driver 120 to the switch units 142, 144, . . . , 14n (refer to node1).

The first switch unit 142 may include a plurality of switches the turning on or off of which may be controlled in response to the switch control signals SW0-SW7.

The second switch unit 144 may include a plurality of switches the turn-on/off of which may be controlled in response to the switch control signals SW0-SW7.

The nth switch unit 14n may include a plurality of switches the turn-on/off of which may be controlled in response to the switch control signals SW0-SW7.

Furthermore, the first switch unit 142 may be configured to correspond to the first page 152 of the cell block 150.

Likewise, the second switch unit 144 may be configured to correspond to the second page 154 of the cell block 150.

Additionally, the nth switch unit 14n may be configured to correspond to the nth page 15n of the cell block 150.

For example, in order to write data of 8 bits, 8 cells need not to be accessed at the same time within the first page 152 as in the prior art.

In an embodiment, for example, control can be performed so that the cells of the 8 pages, respectively, that is, one cell per page, can be accessed and written.

More particularly, control can be performed so that the switches of the 8 pages can be turned by one switch per page in response to the enabled first switch control signals SW0. A load on voltage and current that must be handled by the write driver 120 is reduced because a cell selection path viewed from each page is a single path single path after the write driver 120 supplies a constant voltage. Accordingly, the current supply ability or voltage supply ability of the write driver 120 can be stabilized. Furthermore, the number of write drivers can be reduced depending on a circuit design configuration.

If other signals are added using the above principle, an application range can be further expanded.

FIG. 4 shows the construction of a phase change memory device 200 in accordance with an embodiment.

FIG. 4 shows an example in which a write driver 220 may be used by a main cell block 250 and a redundancy cell block 260 in common.

Referring to FIG. 4, the phase change memory device 200 may include a voltage generator 210, the write driver 220, a switch controller 230 (capable of receiving address signals ADDR), a switch block 240, the main cell block 250, the redundancy cell block 260, and a fuse signal generator 270.

The voltage generator 210, the write driver 220, the switch controller 230, and the switch block 240 are redundant with those of FIG. 1, and thus a detailed description thereof is omitted.

In general, the redundancy cell block 260 may be provided in order to repair cells other than normal cells, that is, the main cell block 250. In the prior art, an additional write driver for the redundancy cell block 260 is provided.

In accordance with an embodiment, if the fuse signal of the fuse signal generator 270 is used and the switch control signals of the switch controller 230 and the switch block 240 are used, the write driver 220 may be used in the redundancy cell block 260.

That is, since a disabled fuse signal from the fuse signal generator 270 may be supplied to normal cells, the path of voltage from the write driver 220 may reach the main cell block 250 in response to the switch control signals of the switch block 240.

If a failure cell within the main cell block 250 is sought to be repaired, the fuse signal generator 270 may supply the fuse signal and the path of voltage from the write driver 220 may reach the redundancy cell block 260 in response to the switch control signals of the switch block 240.

Although various embodiments have been described above, other signals can be used in addition to the fuse signal.

In accordance with this technology, by regularizing the supply of an electric current from the write driver of the semiconductor memory device, a write operation can be stabilized, the number of write drivers, and thus area efficiency can be improved.

While various embodiments have been described above, it will be understood to those skilled in the art that the embodiments described are by way of example only. Accordingly, the semiconductor memory device described herein should not be limited based on the described embodiments.

What is claimed is:

1. A semiconductor memory device, comprising:
a write driver configured to provide voltage necessary for a write operation when the write operation is performed;
a switch block connected to the write driver and configured to control a path of the write voltage; and
a cell block connected to the switch block,
wherein a constant voltage is supplied to a node leading to a cell selection path within the cell block using the write driver as a voltage source.

2. The semiconductor memory device according to claim 1, wherein:
is the switch block comprises a plurality of switch units, and
whether or not to turn on switches within the plurality of switch units is controlled when the write operation is performed.

3. The semiconductor memory device according to claim 2, wherein when the write operation is performed, substantially identical write voltage and write current are supplied via the switches of each of the switch units.

4. The semiconductor memory device according to claim 2, further comprising a switch controller configured to control the switch block, wherein the switch controller controls a path of the write current from the write driver to the switch unit as a single path by decoding address signals and supplying switch control signals to the switch block.

5. The semiconductor memory device according to claim 1, further comprising a fuse signal generator connected to the cell block wherein the cell block comprises a main cell block and a redundancy cell block.

6. The semiconductor memory device according to claim 1, further comprising a voltage generator configured to supply a voltage to the write driver.

7. A semiconductor memory device, comprising:
a write driver configured to provide voltage necessary for a write operation when the write operation is performed;
a cell block configured to comprise a plurality of pages into which data is written using the voltage received from the write driver when the write operation is performed; and
a switch block provided between the write driver and the cell block and configured to provide a path of the write voltage from the write driver to the cell block,
wherein the switch block comprises a plurality of switch units, and
when the plurality of switch units is provided to correspond to the respective pages, a cell selection path between the write driver and each of the pages is a single path.

8. The semiconductor memory device according to claim 7, wherein:
the plurality of switch units receives a plurality of switch control signals, and
when the write operation is performed, whether or not to turn on switches within the plurality of switch units is controlled in response to the switch control signals.

9. The semiconductor memory device according to claim 8, wherein when the write operation is performed, some of the switches of the switch units are substantially simultaneously selected by one switch per switch unit in order to provide a write path.

10. The semiconductor memory device according to claim 8, wherein the plurality of switch control signals is generated by decoding address signals.

11. The semiconductor memory device according to claim 7, further comprising a fuse signal generator connected to the cell block wherein the cell block comprises a main cell block and a redundancy cell block.

12. The semiconductor memory device according to claim 11, further comprising a voltage generator configured to supply a voltage to the write driver.
